(19) United States
(12) Patent Application Publication
(10) Pub. No.: US 2024/0339474 A1
(43) Pub. Date: Oct. 10, 2024

(54) LIGHT DETECTION DEVICE AND ELECTRONIC APPARATUS

(71) Applicant: SONY SEMICONDUCTOR SOLUTIONS CORPORATION, KANAGAWA (JP)

(72) Inventors: TAKAHIRO MAYUMI, KANAGAWA (JP); TOSHIAKI ONO, KANAGAWA (JP)

(21) Appl. No.: 18/292,638

(22) PCT Filed: Mar. 8, 2022
(86) PCT No.: PCT/JP2022/009863

§ 371 Date: Jan. 26, 2024

(30) Foreign Application Priority Data
Aug. 31, 2021 (JP) 2021-141657

(51) Int. Cl. H01L 27/146

(52) U.S. Cl. CPC H01L 27/14634; H01L 27/14636; H01L 27/1469

(57) ABSTRACT

The present disclosure relates to a light detection device and an electronic apparatus that are configured to be able to increase the circuit occupancy area within a substrate. Provided is a light detection device including: a first semiconductor substrate that includes a pixel portion in which a plurality of pixels each including a photoelectric conversion element are arranged; a second semiconductor substrate that includes a logic portion including a signal processing circuit required for processing a signal from the pixel portion; and a support substrate in which wiring is formed, the first semiconductor substrate, the second semiconductor substrate, and the support substrate being stacked, wherein electrical connection between wiring in the second semiconductor substrate and the support substrate is performed using a through via, a first through via is formed in the second semiconductor substrate, a second through-via is formed in the support substrate, and the first through via having a diameter smaller than that of the second through-via. The present disclosure can be applied to, for example, solid state imaging devices.

### TECHNICAL FIELD

The present disclosure relates to a light detection device and an electronic apparatus, and more particularly to a light detection device and an electronic apparatus that are configured to be able to increase the circuit occupancy area within a substrate.

### BACKGROUND ART

As a structure of a rear surface irradiation-type solid-state imaging device, there is a structure in which a support substrate is pasted to a lower side of a substrate including a photoelectric conversion element (see PTL 1, for example). In this structure, pitch conversion is performed on solder balls that are used as a rear electrode by forming a re-distribution layer (RDL) on the rear surface side of the support substrate. This is a typical method of a chip size package (CSP) for taking out an electrode from the rear surface side of the substrate.

### CITATION LIST

### Patent Literature

### [PTL 1]

Japanese Translation of PCT Application No. 2013-530511

### SUMMARY

### Technical Problem

In a structure in which a first semiconductor substrate having a pixel portion, a second semiconductor substrate having a logic portion, and a support substrate are stacked, a through-via penetrating both the second semiconductor substrate and the support substrate is required in taking out an electrode from the rear surface side of the substrate. When forming a through-via in the second semiconductor substrate having thickness, a large-diameter through-via is formed since it is difficult to form a small-diameter through-via.

When a large diameter through-via is formed in the second semiconductor substrate, the area occupancy rate of the through-via becomes high, thus reducing the circuit occupancy area. Therefore, a structure for increasing the circuit occupancy area within the substrate is required.

The present disclosure was made in view of such circumstances, and an object thereof is to be able to increase the circuit occupancy area within the substrate.

### Solution to Problem

A light detection device according to one aspect of the present disclosure is a light detection device comprising: a first semiconductor substrate that includes a pixel portion in which a plurality of pixels each including a photoelectric conversion element are arranged: a second semiconductor substrate that includes a logic portion including a signal processing circuit required for processing a signal from the pixel portion; and a support substrate in which wiring is formed, the first semiconductor substrate, the second semiconductor substrate, and the support substrate being stacked, wherein electrical connection between wiring in the second semiconductor substrate and the support substrate is performed using a through-via, a first through-via is formed in the second semiconductor substrate, and a second through-via is formed in the support substrate, the first through-via having a diameter smaller than that of the second through-via.

An electronic apparatus according to one aspect of the present disclosure is an electronic apparatus equipped with a light detection device comprising: a first semiconductor substrate that includes a pixel portion in which a plurality of pixels each including a photoelectric conversion element are arranged: a second semiconductor substrate that includes a logic portion including a signal processing circuit required for processing a signal from the pixel portion; and a support substrate in which wiring is formed, the first semiconductor substrate, the second semiconductor substrate, and the support substrate being stacked, wherein electrical connection between wiring in the second semiconductor substrate and the support substrate is performed using a through-via, a first through-via is formed in the second semiconductor substrate, and a second through-via is formed in the support substrate, the first through-via having a diameter smaller than that of the second through-via.

In the light detection device and the electronic apparatus according to one aspect of the present disclosure, a first semiconductor substrate that includes a pixel portion in which a plurality of pixels each including a photoelectric conversion element are arranged, a second semiconductor substrate that includes a logic portion including a signal processing circuit required for processing a signal from the pixel portion, and a support substrate in which wiring is formed, are stacked.

Also, electrical connection between wiring in the second semiconductor substrate and the support substrate is performed using a through-via, a first through-via is formed in the second semiconductor substrate, and a second through-via is formed in the support substrate, the first through-via having a diameter smaller than that of the second through-via.

The light detection device according to one aspect of the present disclosure may be an independent device or may be an internal block configuring one device.

### BRIEF DESCRIPTION OF DRAWINGS

FIG. 1 is a cross-sectional view showing a configuration example of an embodiment of a light detection device to which the present disclosure is applied.

FIG. 2 is a diagram showing a first example of a method for manufacturing the light detection device of FIG. 1.

FIG. 3 is a diagram showing the first example of the method for manufacturing the light detection device of FIG. 1.

FIG. 4 is a diagram showing a second example of the method for manufacturing the light detection device of FIG. 1.

FIG. 5 is a diagram showing the second example of the method for manufacturing the light detection device of FIG. 1.

FIG. 6 is a diagram showing a structure in which a re-distribution layer is formed on the rear surface side of a support substrate.

FIG. 7 is a cross-sectional view showing another configuration example of an embodiment of a light detection device to which the present disclosure is applied.

FIG. 8 is a diagram showing an example of a method for manufacturing the light detection device of FIG. 7.

FIG. 9 is a diagram showing an example of the method for manufacturing the light detection device of FIG. 7.

FIG. 10 is a block diagram showing a configuration example of an electronic apparatus equipped with a light detection device to which the present disclosure is applied.

### DESCRIPTION OF EMBODIMENTS

### 1. First Embodiment

### (Cross-Sectional Structure)

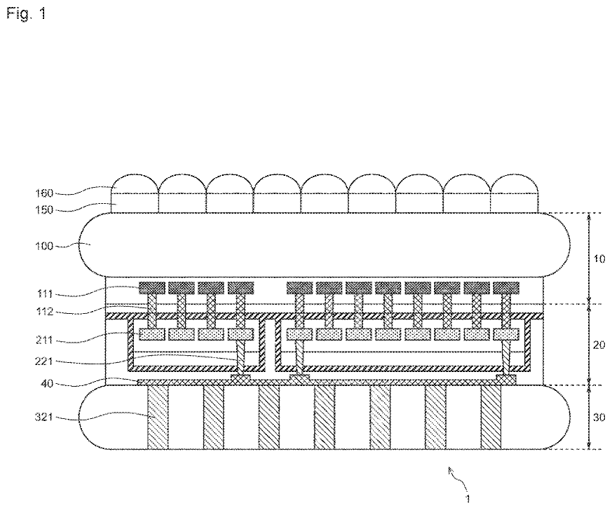

FIG. 1 is a cross-sectional view showing a configuration example of an embodiment of a light detection device to which the present disclosure is applied.

In FIG. 1, a light detection device 1 includes three substrates; a first semiconductor substrate 10, a second semiconductor substrate 20, and a support substrate 30. The first semiconductor substrate 10, the second semiconductor substrate 20, and the support substrate 30 are stacked in this order, and these three substrates are pasted together.

The first semiconductor substrate 10 is composed of, for example, a silicon substrate. The first semiconductor substrate 10 includes an image sensor 100 such as a CIS (CMOS Image Sensor). The image sensor 100 includes a pixel portion in which a plurality of pixels are arranged in a matrix. In the pixel portion, a photodiode is formed as a photoelectric conversion element. A color filter 150 and an on-chip micro lens 160 are formed on the light radiation side of each pixel.

The second semiconductor substrate 20 is composed of, for example, a silicon substrate. The width of the second semiconductor substrate 20 is narrower than that of the first semiconductor substrate 10. The second semiconductor substrate 20 includes a logic portion including a signal processing circuit required for processing a signal from the pixel portion. The logic portion may include a control circuit, a memory circuit and the like in addition to the signal processing circuit. A terminal 111 of the first semiconductor substrate 10 and a terminal 211 of the second semiconductor substrate 20 are electrically connected by wiring 112. The wiring 112 is made of a conductive material such as copper (Cu).

The support substrate 30 is a substrate that has a wiring layer and is used for connecting a signal related to the first semiconductor substrate 10 and the second semiconductor substrate 20 and a power source. Only wiring is formed in the support substrate 30, and a circuit element such as a transistor is not formed.

A re-distribution layer 40 is formed between the second semiconductor substrate 20 and the support substrate 30. The re-distribution layer 40 is made of a conductive material such as copper (Cu). By forming the re-distribution layer 40 on the front surface side of the support substrate 30 (on the second semiconductor substrate 20 side), the wiring of the second semiconductor substrate 20 and the wiring of the support substrate 30 are electrically connected. The re-distribution layer 40 can also be referred to as a wiring layer since it includes wiring that electrically connects the wiring of the second semiconductor substrate 20 and the wiring of the support substrate 30.

In the following description, a first surface of the support substrate 30 on the second semiconductor substrate 20 is referred to as a front surface side, and a second surface opposite to the first surface is referred to as a rear surface side. Similarly, a first surface of the second semiconductor substrate 20 on the first semiconductor substrate 10 side is referred to as a front surface side, and a second surface opposite to the first surface *on the support substrate 30 side) is referred to as a rear surface side. Also, a surface of the first semiconductor substrate 10 on the second semiconductor substrate 20 side is referred to as a rare surface side.

A through-via 221 is formed in the second semiconductor substrate 20. The through-via 221 is formed in such a manner as to penetrate the substrate from under the terminal 211 to reach the re-distribution layer 40. The through-via 221 is made of a conductive material such as a copper (Cu) and electrically connects the terminal 211 and the re-distribution layer 40.

A through-via 321 is formed in the support substrate 30. The through-via 321 is formed in such a manner as to penetrate the substrate. The through-via 321 is made of a conductive material such as copper (Cu) and electrically connects the re-distribution layer 40 and a solder ball (not shown).

The electrical connection between the wiring of the second semiconductor substrate 20 and the wiring of the support substrate 30 is done using the through-via 221 and the through-via 321. The second semiconductor substrate 20 is electrically connected to the re-distribution layer 40 via the through-via 221, and the support substrate 30 is electrically connected to the re-distribution layer 40 via the through-via 321. Since the wiring interval is converted into a solder pitch (solder ball interval) by the re-distribution layer 40 formed between the second semiconductor substrate 20 and the support substrate 30, the diameter of the through-via 221 formed in the second semiconductor substrate 20 can be made smaller than the diameter of the through-via 321 formed in the support substrate 30.

For example, in the cross-sectional view shown in FIG. 1, seven through-vias 321 are formed in the support substrate 30, but since each of these through-vias 321 is connected to the solder ball, the interval of the through-vias 321 correspond to the solder pitch. On the other hand, in the cross-sectional view shown in FIG. 1, three through-vias 221 are formed in the second semiconductor substrate 20, but since the interval is converted into the solder pitch by the re-distribution layer 40 between the second semiconductor substrate 20 and the support substrate 30, it is not necessary to make the arrangement of the through-vias 221 correspond to the solder pitch.

Thus, the light detection device 1 can have a structure in which the through-vias 221 formed in the second semiconductor substrate 20 and the through-vias 321 formed in the support substrate 30 are through-vias with different aspect ratios. By making the diameter of the through-vias 221 smaller than the diameter of the through-vias 321, through-vias with a smaller diameter can be formed as the through-vias 221 in the second semiconductor substrate 20. Accordingly, the circuit occupancy area within the second semiconductor substrate 20 can be increased while reducing the occupancy area of the through-vias 221 in the second semiconductor substrate 20.

### First Example of Manufacturing Method

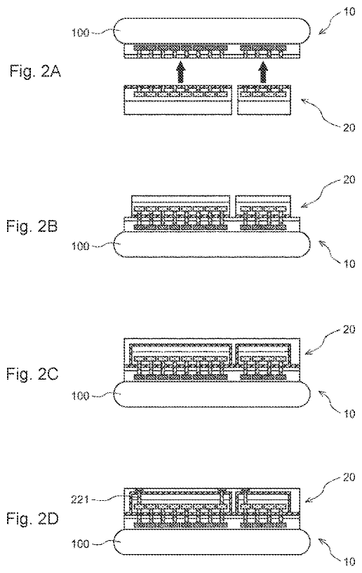

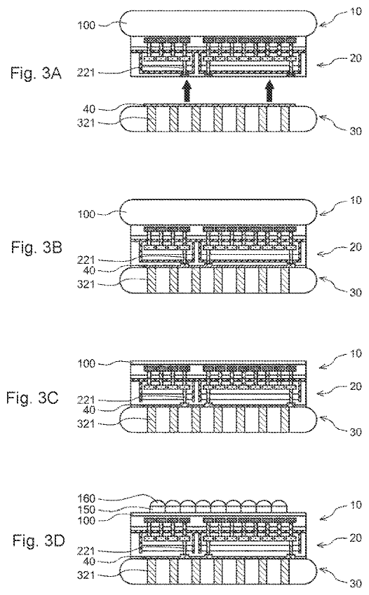

FIGS. 2 and 3 are diagrams showing a first example of a manufacturing method including steps for forming the structure of the light detection device 1 shown in FIG. 1.

In the step shown in A in FIG. 2, the rear surface side of the first semiconductor substrate 10 including the image sensor 100 and the front surface side of the second semiconductor substrate 20 are pasted together by a chip on wafer (CoW) step. In the step shown in B in FIG. 2, the silicon of the second semiconductor substrate 20 is made thin. In the step shown in C in FIG. 2, steps on the rear surface side of the second semiconductor substrate 20 are buried and flattened.

In the step shown in D in FIG. 2, the through-vias 221 are formed on the rear surface side of the second semiconductor substrate 20. The diameter of the through-vias 221 is smaller than the diameter of the through-vias 321 formed in the support substrate 30.

In the step shown in E in FIG. 3, the support substrate 30 to be pasted to the rear surface side of the second semiconductor substrate 20 is prepared. The through-vias 321 are formed in the support substrate 30 in advance. The diameter of the through-vias 321 is larger than the diameter of the through-vias 221 formed in the second semiconductor substrate 20. The re-distribution layer 40 is formed on the front surface side of the support substrate 30 in advance.

In the step shown in F in FIG. 3, the rear surface side of the second semiconductor substrate 20 stacked on the first semiconductor substrate 10 and the front surface side of the support substrate 30 are pasted together. As a result, the re-distribution layer 40 is formed between the second semiconductor substrate 20 and the support substrate 30, and the wiring of the second semiconductor substrate 20 and the wiring of the support substrate 30 are electrically connected.

In the step shown in G in FIG. 3, the silicon of the first semiconductor substrate 10 is made thin. In the step shown in H in FIG. 3, the color filter 150 and the on-chip micro lens 160 are formed on the silicon of the first semiconductor substrate 10. Thereafter, the light detection device 1 having the structure shown in FIG. 1 can be manufactured through a predetermined step.

In the foregoing manufacturing method, when forming the through-vias 221 in the second semiconductor substrate 20 in the step shown in D in FIG. 2, since it is not necessary to form a through-via of a low aspect ratio penetrating the second semiconductor substrate 20 and the support substrate 30, a through-via having a high aspect ratio can be formed in the second semiconductor substrate 20. Therefore, the occupancy area of the through-vias 221 within the second semiconductor substrate 20 can be reduced, and the circuit occupancy area can be increased.

Further, before pasting the support substrate 30 to the second semiconductor substrate 20 in the step shown in F in FIG. 3, the re-distribution layer 40 and the through-vias 321 are formed in the support substrate 30 in advance, so that the processing up to chip-size packaging can be completed immediately by simply pasting the support substrate 30. Thus, the time it takes to completely finish the light detection device 1 can be shortened, thereby realizing short TAT (turn-around-time).

### Second Example of Manufacturing Method

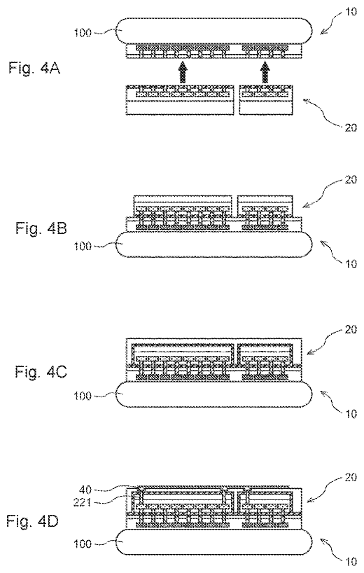

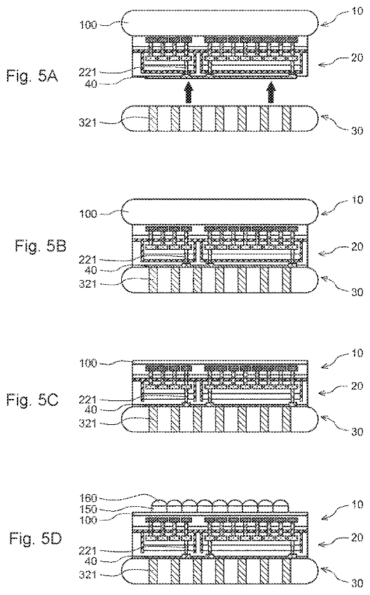

FIGS. 4 and 5 are diagrams showing a second example of the manufacturing method including steps for forming the structure of the light detection device 1 shown in FIG. 1.

As with the steps shown in A to C in FIG. 2, in the steps shown in A to C in FIG. 4, the first semiconductor substrate 10 and the second semiconductor substrate 20 are pasted together, and the silicon of the second semiconductor substrate 20 is made thin and flat.

In the step shown in D in FIG. 4, the through-vias 221 are formed on the rear surface side of the second semiconductor substrate 20. Also, in the step shown in D in FIG. 4, the re-distribution layer 40 is formed on the rear surface side of the second semiconductor substrate 20. In the step shown in E in FIG. 5, the support substrate 30 is prepared, by the re-distribution layer 40 is not formed in the front surface side of the support substrate 30, unlike the step shown in E in FIG. 3.

In the step shown in F in FIG. 5, the rear surface side of the second semiconductor substrate 20 and the front surface side of the support substrate 30 are pasted together. By forming the re-distribution layer 40 between the second semiconductor substrate 20 and the support substrate 30, the wiring of the second semiconductor substrate 20 and the wiring of the support substrate 30 are electrically connected.

In the steps shown in G and H in FIG. 5, as with the steps shown in G and H in FIG. 3, the silicon of the first semiconductor substrate 10 is made thin, and the color filter 150 and the on-chip micro lens 160 are formed. Thereafter, the light detection device 1 having the structure shown in FIG. 1 can be manufactured through a predetermined step.

In this manufacturing method, instead of forming the re-distribution layer 40 on the front surface side of the support substrate 30 (on the second semiconductor substrate 20 side) as in the step shown in E in FIG. 3, the re-distribution layer 40 is formed on the rear surface side of the second semiconductor substrate 20 (on the support substrate 30 side) as in the step shown in D in FIG. 4, thereby forming the re-distribution layer 40 between the second semiconductor substrate 20 and the support substrate 30.

Even when going through these steps, since it is not necessary to form a through-via of a low aspect ratio penetrating the second semiconductor substrate 20 and the support substrate 30 when forming the through-vias 221 in the second semiconductor substrate 20 in the step shown in D in FIG. 4, a through-via with a high aspect ratio can be formed in the second semiconductor substrate 20. Therefore, the occupancy area of the through-vias 221 within the second semiconductor substrate 20 can be reduced, and the circuit occupancy area can be increased.

In addition, the through-vias 321 are formed in the support substrate 30 in advance prior to pasting the support substrate 30 to the second semiconductor substrate 20 in the step shown in F in FIG. 5, so that the processing up to chip-size packaging can be completed immediately by simply pasting the support substrate 30. Thus, the time it takes to completely finish the light detection device 1 can be shortened, thereby realizing short TAT (turn-around-time).

### Overview of Present Disclosure

The light detection device 1 of FIG. 1 has a structure in which the re-distribution layer 40 is formed between the second semiconductor substrate 20 and the support substrate 30, and the through-vias 221 formed in the second semiconductor substrate 20 and the through-vias 321 formed in the support substrate 30 have different aspect ratios, thereby increasing the circuit occupancy area of the second semiconductor substrate 20.

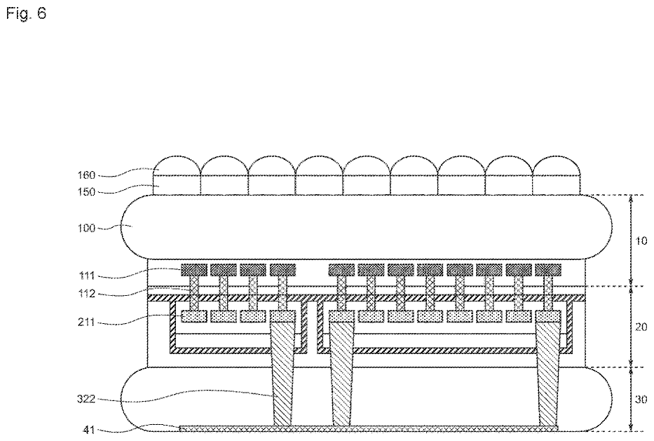

On the other hand, for comparison, FIG. 6 shows a structure in which pitch conversion is performed on solder balls that are used as a rear electrode by forming a re-distribution layer on the rear surface side of the support substrate, as a structure in which the electrode is taken out from the rear surface side in a stacked image sensor.

Although FIG. 6 shows a structure in which a re-distribution layer 41 is formed on the rear surface side of the support substrate 30, this structure requires through-vias 322 penetrating both the second semiconductor substrate 20 and the support substrate 30. When forming the through-vias 322 in the second semiconductor substrate 20 having thickness, since it is difficult to form small-diameter through-vias, it is inevitable that large-diameter through-vias, or through-vias with a low aspect ratio, are used.

Therefore, when large-diameter through-vias are formed, inside the second semiconductor substrate 20, the area occupancy rate of the through-vias becomes high and the circuit occupancy area becomes low. For this reason, a structure for increasing the circuit occupancy area within the substrate is required, and the present disclosure proposes the structure of the light detection device 1 shown in FIG. 1. In the light detection device 1 shown in FIG. 1, since the re-distribution layer 40 is formed between the second semiconductor substrate 20 and the support substrate 30, it is not necessary to form through-vias having a low aspect ratio that penetrate a plurality of substrates, thereby ensuring a sufficient circuit area.

Moreover, the structure shown in FIG. 6 takes a long processing time because the through-vias 322 penetrating both the second semiconductor substrate 20 and the support substrate 30 need to be formed after pasting the second semiconductor substrate 20 and the support substrate 30 together. On the other hand, in the method for manufacturing the light detection device 1 shown in FIG. 1, when forming the re-distribution layer 40 on the front surface side of the support substrate 30 (E of FIG. 3), the formation of the re-distribution layer 40 and the formation of the through-vias 321 corresponding to the solar pitch can independently be prepared only with the support substrate 30, thereby realizing short TAT. In addition, when forming the re-distribution layer 40 on the rear surface side of the second semiconductor substrate 20 (D of FIG. 4, E of FIG. 5), the formation of the through-vias 321 corresponding to the solder pitch can independently prepared only with the support substrate 30, thereby realizing short TAT.

### 2. Second Embodiment

### Cross-Sectional Structure

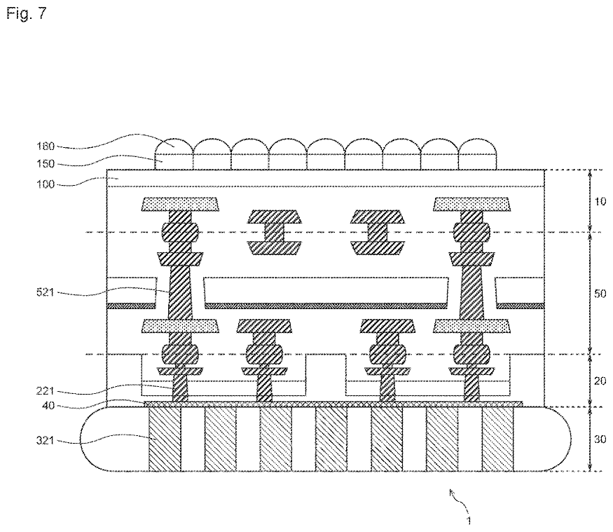

FIG. 7 is a cross-sectional view showing another configuration example of an embodiment of a light detection device to which the present disclosure is applied.

In FIG. 7, compared to the structure shown in FIG. 1, the light detection device 1 has a structure having a third semiconductor substrate 50 between the first semiconductor substrate 10 and the second semiconductor substrate 20 in addition to the three substrates, i.e., the first semiconductor substrate 10, the second semiconductor substrate 20, and the support substrate 30.

The first semiconductor substrate 10 includes the image sensor 100. The image sensor 100 includes a pixel portion, and a photodiode is formed in each pixel. The color filter 150 and the on-chip micro lens 160 are formed on the light radiation side of each pixel.

The second semiconductor substrate 20 has a logic portion that includes a circuit such as a signal processing circuit. The support substrate 30 is a substrate that has a wiring layer and is used for connecting a signal and a power source.

The re-distribution layer 40 is formed between the second semiconductor substrate 20 and the support substrate 30. The re-distribution layer 40 is connected to the second semiconductor substrate 20 via through-vias 221 and connected to the support substrate 30 via through-vias 321. Since the wiring interval is converted into a solder pitch by the re-distribution layer 40 formed between the second semiconductor substrate 20 and the support substrate 30, the diameter of the through-vias 221 formed in the second semiconductor substrate 20 can be made smaller than the diameter of the through-vias 321 formed in the support substrate 30.

The third semiconductor substrate 50 is made of, for example, a silicon substrate. For example, the third semiconductor substrate 50 has a logic portion that includes a circuit such as a signal processing circuit, a control circuit, and a memory circuit. Through-vias 521 are formed in the third semiconductor substrate 50. The third semiconductor substrate 50 is electrically connected to the wiring of the first semiconductor substrate 10 and the wiring of the second semiconductor substrate 20 via the through-vias 521.

The diameter of the through-vias 521 formed in the third semiconductor substrate 50 can be made smaller than the diameter of the through-vias 321 formed in the support substrate 30. That is, in the cross-sectional view in FIG. 7, two through-vias 521 are formed in the third semiconductor substrate 50 are converted into a solder pitch by the re-distribution layer 40 formed between the second semiconductor substrate 20 and the support substrate 30. Therefore, the arrangement of the through-vias 521 does not have to correspond to the solder pitch. Therefore, the through-vias 521 can be configured to have an aspect ratio different from that of the through-vias 321.

In the light detection device 1 shown in FIG. 7, the circuit occupancy area within the second semiconductor substrate 20 is increased and the occupancy area of the through-vias 521 within the third semiconductor substrate 50, to increase the circuit occupancy area. Accordingly, the circuit occupancy area can be further increased.

Note that in the relationship between the diameter of the through-vias 221 formed in the second semiconductor substrate 20 and the diameter of the through-vias 521 formed in the third semiconductor substrate 50, although the relationship in size between the diameters may change depending on the thicknesses of the substrates, the fact remains that the diameters of the through-vias 221 and the through-vias 521 are smaller than the diameter of the through-vias 321.

### Examples of Manufacturing Method

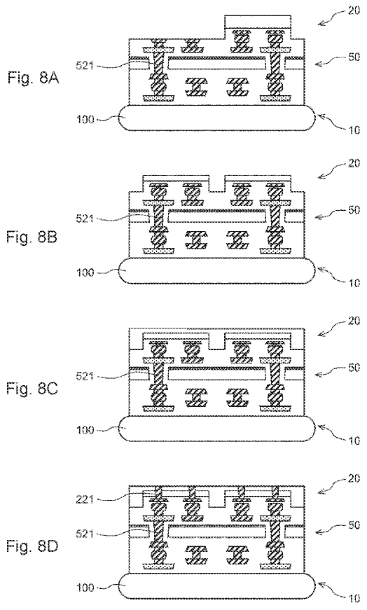

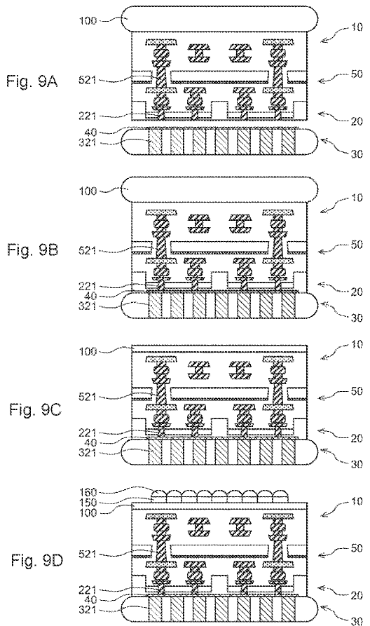

FIGS. 8 and 9 are diagrams showing examples of the manufacturing method including the step of forming the structure of the light detection device 1 shown in FIG. 7.

In the steps shown in A and B of FIG. 8, by the CoW step, the second semiconductor substrate 20 is pasted to the third semiconductor substrate 50 pasted to the first semiconductor substrate 10. The through-vias 521 are formed in the third semiconductor substrate 50, and the diameter of the through-vias 521 is smaller than the diameter of the through-vias 321 formed in the support substrate 30.

In the step shown in C in FIG. 8, steps on the rear surface side of the second semiconductor substrate 20 are buried and flattened. In the step shown in D in FIG. 8, the through-vias 221 are formed on the rear surface side of the second semiconductor substrate 20. The diameter of the through-vias 221 is smaller than the diameter of the through-vias 321 formed in the support substrate 30.

In the step shown in E in FIG. 9, the support substrate 30 to be pasted to the rear surface side of the second semiconductor substrate 20 is prepared. The through-vias 321 are formed in the support substrate 30 in advance. The diameter of the through-vias 321 is larger than the diameters of the through-vias 221 of the through-vias 521. The re-distribution layer 40 is formed on the front surface side of the support substrate 30 in advance.

In the step shown in F in FIG. 9, the rear surface side of the second semiconductor substrate 20 stacked on the first semiconductor substrate 10 and the third semiconductor substrate 50 is pasted to the front surface side of the support substrate 30. As a result, the re-distribution layer 40 is formed between the second semiconductor substrate 20 and the support substrate 30, and the wiring of the second semiconductor substrate 20 and the wiring of the support substrate 30 are electrically connected.

In the step shown in G in FIG. 9, the silicon of the first semiconductor substrate 10 is made thin. In the step shown in H in FIG. 9, the color filter 150 and the on-chip micro lens 160 are formed on the silicon of the first semiconductor substrate 10. Thereafter, the light detection device 1 having the structure shown in FIG. 7 can be manufactured through a predetermined step.

In the foregoing manufacturing method, when forming the through-vias in the second semiconductor substrate 20 and the third semiconductor substrate 50, since it is not necessary to form a through-via of a low aspect ratio penetrating the substrates, a through-via having a high aspect ratio can be formed in the second semiconductor substrate 20 and the third semiconductor substrate 50. Thus, the occupancy area of the through-vias within the semiconductor substrate can be reduced, and the circuit occupancy area can be increased.

In addition, before pasting the support substrate 30 to the second semiconductor substrate 20 in the step shown in F in FIG. 9, TAT can be realized by forming the re-distribution layer 40 and the through-vias 321 in the support substrate 30 in advance.

Although the structure in which the third semiconductor substrate 50 is added between the first semiconductor substrate 10 and the second semiconductor substrate 20 has been described, the number of semiconductor substrates to be added between the first semiconductor substrate 10 and the second semiconductor substrate 20 is not limited to 1 and may be 2 or more. In other words, as long as the re-distribution layer 40 is formed between the second semiconductor substrate 20 and the support substrate 30, an increase in the number of semiconductor substrates to be stacked can be accommodated, and the diameter of the through-vias to be formed in the added semiconductor substrate can be made smaller than the diameter of the through-vias 321 formed in the support substrate 30, to increase the circuit occupancy area.

### 3. Modifications

### (Configuration of Solid-State Imaging Device)

The light detection device 1 can be a solid-state imaging device having the image sensor 100 such as a CIS. The image sensor 100 can have a rear surface irradiation-type structure in which light is made incident from an upper layer (rear surface side) opposite to the wiring layer side (front surface side) formed in a lower layer as viewed from the semiconductor substrate.

The structure to which the present disclosure is applied (the structure shown in FIG. 1 or FIG. 7) can be applied not only to a solid-state imaging device with a CMOS (Complementary Metal Oxide Semiconductor)-type image sensor, but also to a solid-state imaging device having a CCD (Charge Coupled Device)-type image sensor. Further, the structure to which the present disclosure is applied (the structure shown in FIG. 1 or FIG. 7) can be applied not only to a light detection device such as a solid-state imaging device, but also to semiconductor devices in general.

### (Configuration of Electronic Apparatus)

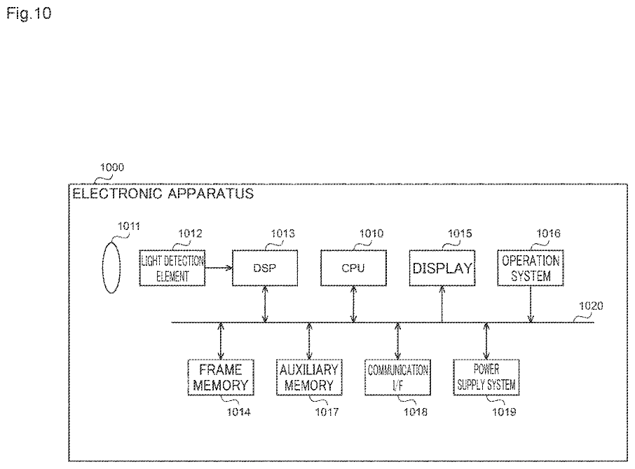

The light detection device to which the present disclosure is applied can be mounted in electronic apparatuses such as smartphones, tablet terminals, mobile phones, digital still cameras, and digital video cameras. FIG. 10 is a block diagram showing a configuration example of the electronic apparatus equipped with the light detection device to which the present disclosure is applied.

In FIG. 10, an electronic apparatus 1000 has an imaging system composed of an optical system 1011 including a lens group, a light detection element 1012 having a structure corresponding to the light detection device 1 of FIG. 1, and a DSP (Digital Signal Processor) 1013 which is a camera signal processing unit. In the electronic apparatus 1000, in addition to the imaging system, a CPU (Central Processing Unit) 1010, a frame memory 1014, a display 1015, an operation system 1016, an auxiliary memory 1017, a communication I/F 1018, and a power supply system 1019 are connected to one another via a bus 1020.

The CPU 1010 controls the operation of each unit of the electronic apparatus 1000.

The optical system 1011 captures incident light (image light) from a subject and forms an image on a light detection surface of the light detection element 1012. The light detection element 1012 converts an amount of incident light, which forms an image on the light detection surface by the optical system 1011, into an electrical signal for each pixel and outputs the electrical signal as a signal. The DSP 1013 performs predetermined signal processing on the signal output from the light detection element 1012.

The frame memory 1014 temporarily records image data of a still image or a video captured by the imaging system. The display 1015 is a liquid crystal display or an organic EL display, and displays a still image or a video captured by the imaging system. The operation system 1016 issues an operation command for various functions of the electronic apparatus 1000 in response to a user operation.

The auxiliary memory 1017 is a storage medium including a semiconductor memory such as a flash memory, and records image data of a still image or a video captured by the imaging system. The communication I/F 1018 has a communication module corresponding to a predetermined communication method, and transmits image data of a still image or a video captured by the imaging system to other apparatuses via a network.

The power supply system 1019 appropriately supplies various power supplies functioning as the operating power supply, to the CPU 1010, the DSP 1013, the frame memory 1014, the display 1015, the operation system 1016, the auxiliary memory 1017, and the communication I/F 1018.

Note that the embodiments of the present disclosure are not limited to those described above and can be modified in various manners without departing from the gist of the present disclosure. The advantageous effects described in the present specification are merely exemplary and are not limited, and other advantageous effects may be obtained.

The present disclosure can be also configured as follows:

(1)

A light detection device, comprising:
a first semiconductor substrate that includes a pixel portion in which a plurality of pixels each including a photoelectric conversion element are arranged;
a second semiconductor substrate that includes a logic portion including a signal processing circuit required for processing a signal from the pixel portion; and
a support substrate in which wiring is formed,
the first semiconductor substrate, the second semiconductor substrate, and the support substrate being stacked,
wherein electrical connection between wiring in the second semiconductor substrate and the support substrate is performed using a through-via,
a first through-via is formed in the second semiconductor substrate,
a second through-via is formed in the support substrate, and
the first through-via having a diameter smaller than that of the second through-via.
   (2)

The light detection device according to (1) above, wherein a wiring layer is formed between the second semiconductor substrate and the support substrate, the second semiconductor substrate is electrically connected to the wiring layer via the first through-via, and
the support substrate is electrically connected to the wiring layer via the second through-via.
   (3)

The light detection device according to (1) or (2) above, wherein a third semiconductor substrate is stacked between the first semiconductor substrate and the second semiconductor substrate.

(4)

The light detection device according to (3) above, wherein a third through-via is formed in the third semiconductor substrate,
the third through-via having a diameter smaller than that of the second through-via.
   (5)

The light detection device according to (3) or (4) above, wherein one or a plurality of the third semiconductor substrates are stacked.

(6)

The light detection device according to any one of (2) to (5) above, wherein in pasting the second semiconductor substrate and the support substrate together, the wiring layer and the second through-via are formed in the support substrate in advance.

(7)

The light detection device according to any one of (2) to (5) above, wherein in pasting the second semiconductor substrate and the support substrate together, when the wiring layer is formed in the second semiconductor substrate, the second through-via is formed in the support substrate in advance.

(8)

The light detection device according to any one of (1) to (7) above, wherein the second semiconductor substrate has a width narrower than that of the first semiconductor substrate.

(9)

The light detection device according to any one of (1) to (8) above, wherein the support substrate does not have a circuit element formed therein.

(10)

The light detection device according to any one of (2) to (9) above, wherein the wiring layer is a re-distribution layer.

(11)

An electronic apparatus equipped with a light detection device comprising:
a first semiconductor substrate that includes a pixel portion in which a plurality of pixels each including a photoelectric conversion element are arranged;
a second semiconductor substrate that includes a logic portion including a signal processing circuit required for processing a signal from the pixel portion; and
a support substrate in which wiring is formed,
the first semiconductor substrate, the second semiconductor substrate, and the support substrate being stacked,
wherein electrical connection between wiring in the second semiconductor substrate and the support substrate is performed using a through-via,
a first through-via is formed in the second semiconductor substrate,
a second through-via is formed in the support substrate, and
the first through-via having a diameter smaller than that of the second through-via.

### REFERENCE SIGNS LIST

1 Light detection device
10 First semiconductor substrate
20 Second semiconductor substrate
30 Support substrate
40 Re-distribution layer
50 Third semiconductor substrate
100 Image sensor
150 Color filter
160 On-chip micro lens
221 Through-via
321 Through-via
521 Through-via
1000 Electronic apparatus
1012 Light detection element

1. A light detection device, comprising:
a first semiconductor substrate that includes a pixel portion in which a plurality of pixels each including a photoelectric conversion element are arranged;
a second semiconductor substrate that includes a logic portion including a signal processing circuit required for processing a signal from the pixel portion; and
a support substrate in which wiring is formed,
the first semiconductor substrate, the second semiconductor substrate, and the support substrate being stacked,
wherein electrical connection between wiring in the second semiconductor substrate and the support substrate is performed using a through-via,
a first through-via is formed in the second semiconductor substrate,
a second through-via is formed in the support substrate, and
the first through-via having a diameter smaller than that of the second through-via.

2. The light detection device according to claim 1, wherein a wiring layer is formed between the second semiconductor substrate and the support substrate,
the second semiconductor substrate is electrically connected to the wiring layer via the first through-via, and
the support substrate is electrically connected to the wiring layer via the second through-via.

3. The light detection device according to claim 1, wherein a third semiconductor substrate is stacked between the first semiconductor substrate and the second semiconductor substrate.

4. The light detection device according to claim 3, wherein a third through-via is formed in the third semiconductor substrate,
the third through-via having a diameter smaller than that of the second through-via.

5. The light detection device according to claim 3, wherein one or a plurality of the third semiconductor substrates are stacked.

6. The light detection device according to claim 2, wherein in pasting the second semiconductor substrate and the support substrate together, the wiring layer and the second through-via are formed in the support substrate in advance.

7. The light detection device according to claim 2, wherein in pasting the second semiconductor substrate and the support substrate together, when the wiring layer is formed in the second semiconductor substrate, the second through-via is formed in the support substrate in advance.

8. The light detection device according to claim 1, wherein the second semiconductor substrate has a width narrower than that of the first semiconductor substrate.

9. The light detection device according to claim 1, wherein the support substrate does not have a circuit element formed therein.

10. The light detection device according to claim 2, wherein the wiring layer is a re-distribution layer.

11. An electronic apparatus equipped with a light detection device comprising:
a first semiconductor substrate that includes a pixel portion in which a plurality of pixels each including a photoelectric conversion element are arranged;
a second semiconductor substrate that includes a logic portion including a signal processing circuit required for processing a signal from the pixel portion; and
a support substrate in which wiring is formed,
the first semiconductor substrate, the second semiconductor substrate, and the support substrate being stacked,
wherein electrical connection between wiring in the second semiconductor substrate and the support substrate is performed using a through-via,
a first through-via is formed in the second semiconductor substrate,
a second through-via is formed in the support substrate, and
the first through-via having a diameter smaller than that of the second through-via.
